(19) United States
(12) Patent Application Publication
(10) Pub. No.: US 2008/0067919 A1
(43) Pub. Date: Mar. 20, 2008

(54) Phosphor of White LED and the Manufacturing Method of the Same

(76) Inventors: Jin-Gao WANG, Fujian (CN); Jin-Gao Wang, Fujian (CN)

Correspondence Address: Dr. BANGER SHIA;Int''l Patent Office of Bang Shia, 102 Lindencrest Ct, Sugar Land, TX, 77479-5201, US

(21) Appl. No.: 11/858,067

(22) Filed: Sep. 19, 2007

(30) Foreign Application Priority Data
Sep. 20, 2006 (CN) 200610159447.9

(51) Int. Cl. H01L 33/00; F21V 8/00; H01J 9/02

(52) U.S. Cl. 313/503; 445/46

(57) ABSTRACT

The present invention provides a phosphor of white LED and the manufacturing method of the same, relating to a phosphor of light-emitting material, and more particularly to a high-efficiency phosphor of semiconductor white light emitting diode in sphericized or director-sphericized crystal structure. The general formula (Y₁₋ₓGdₓ)_{3-z}(Al_{1-y}Ga_{y})₅O₁₂:Ce_{z}³⁺, therein 0≦x≦0.45 mol/mol, 0≦y≦0.55 mol/mol, 0.06≦x≦0.12 mol/mol, the sensitizer includes rare sensitizer Ce³⁺ and other aid-sensitizers, where said aid-sensitizer is at least one of Pr, Th, Dy and so on, the concentration of Pr, or Tb, or Dy is individually 5%˜10% of the Ce³⁺'s. the steps as followings: taking out the raw materials for extracting former body, the grain fineness of the sphericized or director-sphericized grain of the former body extracted is 1˜2 um, the extracted former body is mixed with fluxing agent, and composed in H₂/N₂, then treated sequentially in acid-washing, alkali-washing, water-washing processes, next crushing, shifting with 350 meshes screen, examining goods and packaging are carried out in the finishing process. The luminous devices manufactured with said phosphor have high light output with more than 80 lm/w in luminous flux.

### BACKGROUND OF THE INVENTION

1. Field of the Invention

The present invention relates to a phosphor of light-emitting material, and more particularly to a high-efficiency phosphor with more than 80 lm/w in luminous flux of semiconductor white light emitting diode in sphericized or director-sphericized crystal structure.

2. Description of Prior Art

Manufacturing white light emitting diode is a well known technology by means of coating YAG phosphor on a blue light emitting chip and encapsulating. But the luminous flux per watt of the white light emitting diode is decided by the inner quantum efficiency of the blue light chip, the luminousness of the encapsulation and the photoconduction of the phosphor, among of them the photoconduction of the phosphor is vital importance.

After a Japanese company, Nichia Chemical discovered GaN blue light technique in 1996, combining the blue LED and yttrium aluminum garnet to generate white light is discovered and applied to YAG patent (U.S. Pat. No. 5,998,925, U.S. Pat. No. 6,069,440, and CN1268650). Actually, the yttrium aluminum garnet technology was discovered by Biasse a Netherland scientist in 1976, and declared before 20 years. In accordance with the report issued by Nichia, the light intensity of the LED produced before 2005 was 30 lm/w, but after 2006 it was 30˜40 lm/w. in the report issued in Oct. 3, 2006, Nichia would show a LED sample with 100 lm/w in the exhibition at June 2006, and the same goods would come out in the market in December 2006, and declared no breakthrough on the phosphor, but on changing the shape of chip. In the Nichia patent, it is only stressed that eight elements such as Sc, Y, La, Gd, Lu, Al, Ga are matrixes, Ce is a sensitizer, there are five elements more matrixes than three matrix elements issued by Netherlands's scientists such as Y, Al, and Ce. Because the patent host restricted many people to develop the phosphor, and Nichia also did not authorize the use of the patent itself to the outsides, so this technology was restrained for eight years long. So Toyoda Gosei, a Japanese company, was forced to cooperate with three Europe's companies, Tridonic opto-electronic GmbH, Lite GBR and Leuchstoffwerk Beitungen Gmb to develop silicate phosphor. After that, Matrushita also applied the patent of silicate phosphor (Patent No.: WO 03021699).

Lumileds company, a join-venture company of HP and Philip changed the formula of Nichia to add Pr³⁺ working as sensitizer, such as Ce³⁺ and Pr³⁺ consists of sensitizer, so as to emit two lights respectively at wavelength 550 nm and 612 nm, and applied US patents (referring to U.S. Pat. No. 6,352,069 and U.S. Pat. No. 6,417,019) the composition of the phosphor includes (YGd)₃Al₅O₁₂:Ce:Pr. In the same way, Osram Opto, for keeping away from the Nichia patent, took the place of Ce with Tb to apply TAG phosphor patent (WO0193342 and TW555832), in which the composition is Y₃Al₅O₁₂:Ce³⁺.Tb³⁺, so as to emit 545 nm green light.

Osram also applied silicate patent in the same time giving up thoroughly alumo-silicate formula of Nichia to obtain 520 nm green light. A Chinese company in Dalian of Liaoning province, Luming Technology company also applied silicate patent, which not only change the matrix material (alumo-silicate or silicate), but also the sensitizer material (also called sensitizer). Because the spectrum line of Ce³⁺ in Nichia patent is singleness, it is a fatal weakness. The companies of the United State and Germany add Pr and Tb as sensitizer or aid-sensitizer evidently to make the spectrum line different from the Ce³⁺, so that the spectrum performance becomes obviously fuller.

The inventor of the present invention employed Pr³⁺, Dy³⁺, and Tb³⁺ as rare sensitizers in the invention patent umber CN1687307A, so as to obtain 612 nm, 580 nm, 555 nm and 520˜540 nm spectrum lines. It should be pointed that the matrix material of the light emitting phosphor admittedly is important, the sensitizer and aid-sensitizer are more important light emitting materials or sensitizers.

From the yttrium aluminum garnet was discovered by Netherlands's scientist in 1976 to Nichia applied yttrium aluminum garnet patent, the scientists of the United States, Netherlands and Germany obtained many patents in the same way by changing the composition, but they have a general character, the white light phosphors of these patents all are amorphous powder. Meanwhile the LED encapsulated with the phosphors of these patents just only emit 30˜40 lm/w in the light intensity, but unable to exceed 60 lm/w. in the same way, the phosphors in the patents of CN1478855A, CN1539919A, CN1373523A, and CN1840510A all are amorphous powder with 30˜40 lm/w in the photoconduction too.

### OBJECTS AND SUMMARY OF THE INVENTION

It is therefore a main object of the present invention to provide a high-efficiency phosphor of semiconductor white light emitting diode in sphericized or director-sphericized crystal structure and the manufacturing method of the same overcoming the shortcomings of the conventional phosphor of LED, such as low light intensity and lumen efficiency, and the shortcomings of the common light devices, such as low light intensity.

For achieving the object mentioned above, the present invention provides a phosphor of semiconductor white light emitting diode in sphericized or director-sphericized crystal structure with general formula (Y₁₋ₓGdₓ)_{3-z}(Al_{1-y}Ga_{y})₅O₁₂:Ce_{z}³⁺ wherein 0≦x≦0.45 mol/mol, 0≦y≦0.55 mol/mol, 0.06≦x≦0.12 mol/mol, the sensitizer includes rare sensitizer Ce³⁺ and other aid-sensitizers, where said aid-sensitizer is at least one of Pr, Tb, Dy and so on, the concentration of Pr, or Tb, or Dy is individually 5%˜10% of the Ce³⁺'s.

A method of said phosphor of semiconductor white light emitting diode in sphericized or director-sphericized crystal structure provided by the present invention is following steps:
1. The raw material is selected from Y₂O₃, Gd₂O₃, Tb₄O₇, Pr₆O₁₁, Dy₂O₃, Al₂O₃ and Ga₂O₃, the composition formula (Y₁₋ₓGdₓ)_{3-z}(Al_{1-y}Gay)₅O₁₂:Ce_{z}³⁺ wherein 0≦X≦0.45 mol/mol, 0≦Y≦0.55 mol/mol, 0.06≦z≦0.12 mol/mol, Y, Gd, Al and Ga all are the host cation and the host anion, said sensitizer includes rare sensitizer Ce³⁺ and other aid-sensitizers, wherein said aid-sensitizer is at least one of Pr, Tb, Dy and so on, the concentration of Pr, or Th, or Dy is individually 5%10% of the Ce³⁺'s, the purity of the raw material is 4˜5N, and the grain fineness is 1˜2 um.
2. Then taking out the raw materials for extracting former body, the grain fineness of the sphericized or director-sphericized grain of the former body extracted is 1˜2 um.
3. In mixing fluxing agent into the former body, said fluxing agent is 1˜5% of the former body in content, and is at least one of B₂O₃, AlF₃, AlCl₃, BaF₂, NH₄F, NH₄Cl and so on.
4. composition process: composing is took part in at 1300°˜1600° C. for 1˜4 hours in de-oxidation H₂/N₂ reaction.
5. Finishing process: sequentially acid-washing, alkali-washing, water-washing processes. In the acid-washing process the concentration of HNO₃ is 0.5˜5N, the concentration of NH₃.H₂O in the alkali-washing process is 0.5˜5N, in water-washing process distilled water or deionized water is used to wash until getting to neutrality in electricity.
6. Crushing, shifting, examining goods and packaging.

Said former body can be extracted by homogeneous-deposition process or sol-gel process, the value of pH of the homogeneous deposition is controlled in the range from 6.5 to 8.0 by using homogeneous-deposition method, said precipitant is liquid ammonia mixing with Al(OH)₃ with 0.6˜1.2 mol/L concentration in the liquid temperature controlled in the range of 75˜90° C. until generating co-precipitation. By centrifuging, washing, filtering and baking processes the deposition is extracted into YAG former body. Due to the constant concentration of liquid-phase, so the graininess of spherical crystal is kept into almost uniform. Due to the property grains, the powder heat-treated can be kept into complete crystal without needing to crashing, classifying treatments.

By using said sol-gel process the pH value of rare nitrate liquid in the raw material is controlled in the range from 2 to 3 mixing with lemon acid in the ratio of 1:2 of the raw material and the lemon acid, then adding with Aluminum nitric liquid with 0.6˜1.2 mol/L concentration, then adding polyethylene glycol until getting to homogeneous, next mixing with intermixture to compose collosol, after the collosol to be transformed into gelatinous, braking the gelatinous at 110˜120° C. into dry, then the dry gelatinous is grinded into powder, next is sintered at 900° C. for 4˜6 hours to form the former body.

In said finishing process, putting water, corundum sphere and fried powder (got after the treatment in said step 4) into a depolymerizing reactor takes part in de-polymerizing reaction for 1 hour, according to the mass ratio of water:corundum sphere:fried powder=4:1:1. By sifting with 350 meshes standard screen, it should be washed with 0.5˜5NHNO₃ liquor at the range from 80° C. to 90° C., and then centrifuged, next braked at 80° C. for 16 hours, after braking process, it should be crushed and screened with 250 meshes standard screen.

In accordance with luminescent technology, we know that the photo-converting efficiency of the phosphor is decided by eight factors as followings:
1. chemical composition, such as formula; distinguishing what is the host matrix and what is sensitizer, and which is main-sensitizer or aid-sensitizer, is vital important, in which the host matrix is not able to emit light, just only main-sensitizer and aid-sensitizer emit light.
2. Crystal structure and appearance; the appearance of the crystal, such as amorphous, flat, granular, quadratic, spherical shapes and the level of the polymerization degree.
3. composition procedure; there are solidoid-composition process, liquid-phase-composition process, solid-liquid-phase-composition process and spray-on process in the conventional technology, and the composition temperatures are different in different cases.
4. size and distribution regular pattern of the grain; the grains obtained by different procedures are different in size, in the conventional solidoid process, the distribution of the grain is in non-uniform in crashing processing, and the luminous performance is poor, but in the liquid-phase process, the grain is in uniform well, and the luminous performance is good.
5. The spectrum emitted by crystal; it would be a single-line, or several-line, or narrow, or wide, or broad band spectrum.
6. the luminous intensity of crystal; the higher absorption effect of the phosphor is, the higher luminous intensity is, therein said absorption effect is decided by the crystal structure and appearance. Said crystal structure is related tightly to the chemical constitution and the molar absorptivity. Said luminous intensity is related tightly to the crystal appearance.
7. the light decaying exponential; if the crystal appearance is in irregular, and the graininess is in non-conforming, it would occur serious light scattering and stay light, meanwhile the light-emitting efficiency is lower, and huge heat is deposited, as if the radiating effect is not good, the service life of it would be shortened. If the graininess of the powder obtained by mechanical crashing process can get into a certain degree, even if the initial luminous flux is high, but the sustaining ratio is not high, and the light decaying exponential is big.
8. the photoconduction; in the procedure of manufacturing YAG+ chips it is typically classified into undershot, in this chip the quantum efficiency≦1, how to make the quantum efficiency approach to or equal to 1 is decided by the composition procedure, so the photoconduction of the indicating light-emitting chips is shown in lm/w.

According to above description, the chemical constitution decides the wave-length of the spectrum and the crystal structure, and the appearance decides the light intensity, the photoconduction and its service life and so on. The composition procedure affects to the crystal structure and appearance, therefore the constitution, structure, appearance, procedure, spectrum, light-intensity, photoconduction rate, and service life are inter-relative eight factors. Although the chemical constitution is very important, but also the crystal appearance and procedure are more important.

On the sensitizer selecting in the present invention, the 550 nm line of Ce is maintained, the 580 nm line of Dy, the 612 nm line of Pr and the 545 nm line of Tb are added to overcome the shortcoming of the single 550 nm line in the conventional technology, as generating 4200° K. warm white color, adding Pr3+ and Dy3+ lines are very important.

Comparing with the conventional phosphor, the phosphor offered by the present invention has sphericized or director-sphericized crystal structure, simulated graininess, and good consistency features. If the operation condition can be under the serious control, the uniformed director-sphericized crystal can be obtained. The sphericized crystal phosphor has good absorption effect, and higher absorption, and is packaged into LED getting more than 80 lm/w, even to get 100˜160 lm/w hopefully under the careful manufacturing, so as to suit completely to apply as same as the general semiconductor illumination, it also is helpful for reducing the LED production cost.

### DETAILED DESCRIPTION OF PREFERRED EMBODIMENTS

The present invention will be given in a minute description by following preferred embodiments.

### The First Embodiment

1) The raw material is selected from Y₂O₃, Gd₂O₃, CeO₂, Tb₄O₇, Pr₆O₁₁, Dy₂O₃, Al₂O₃ and Ga₂O₃, the composition formula (Y₁₋ₓGdₓ)_{3-z}(Al_{1-y}Gay)₅O₁₂:Ce_{z}³⁺, wherein x is 0 mol/mol, y is 0.45 mol/mol, z is 0.12 mol/mol, Y, Gd, Al and Ga all are the host cation and the host anion, said sensitizer includes rare sensitizer Ce³⁺ and other aid-sensitizers, wherein said aid-sensitizer is Pr, the concentration of Pr is 10% of the Ce³⁺'s, the purity of the raw material is 4N, and the grain fineness is 1.5 um.
2) Then taking out the raw materials for extracting former body by means of homogeneous-deposition process, the pH value of the homogeneous-deposition is controlled in 6.5, the precipitant is liquid ammonia adding with 1.2 mol/L Al(OH)₃ liquor, and mixing up, the temperature of the mixed solution is controlled in 90° C., so as to generate co-deposition, said deposition is treated in centrifuging, washing, filtering and baking processes to extract the sphericized or director-sphericized YAG former body.
3) In mixing fluxing agent B₂O₃ into the former body, said fluxing agent is 1% of the former body in content.
4) composition process: composing is took part in at 1400° C. for 2 hours in de-oxidation H₂/N₂ reaction.
5) Finishing process: sequentially acid-washing, alkali-washing, water-washing processes. In the acid-washing process the concentration of HNO₃ is 0.5N, the concentration of NH₃.H₂O in the alkali-washing process is 5N, in water-washing process distilled water is used to wash until getting to neutrality in electricity.
6) Crushing, shifting with 350 meshes screen, examining goods and packaging.

### The Second Embodiment

Similar to the first embodiment of the present invention, the raw material is selected from Y₂O₃, Gd₂O₃, CeO₂, Tb₄O₇, Pr₆O₁₁, Dy₂O₃, Al₂O₃ and Ga₂O₃, the composition formula (Y₁₋ₓGdₓ)_{3-z}(Al_{1-y}Gay)₅O₁₂:Ce_{z}³⁺, wherein x is 0.2 mol/mol, y is 0.55 mol/mol, z is 0.1 mol/mol, Y, Gd, Al and Ga all are host cation and host anion, said sensitizer includes rare sensitizer Ce³⁺ and other aid-sensitizers, wherein said aid-sensitizer is Tb, the concentration of Tb is 8% of the Ce³⁺'S, the purity of the raw material is 5N, and the grain fineness is 2 um. Then taking out the raw materials for extracting former body by means of homogeneous-deposition process, the pH value of the homogeneous-deposition is controlled in 8, the precipitant is liquid ammonia adding with 0.6 mol/L Al(OH)₃ liquor, and mixing up, the temperature of the mixed solution is controlled in 75° C., so as to generate co-deposition, said deposition is treated in centrifuging, washing, filtering and baking processes to extract the sphericized or director-sphericized YAG former body. Next the former body is mixed with fluxing agents AlF₃ and AlCl₃; said fluxing agents are 5% of the former body in content. Composing is took part in at 1500° C. for 3 hours in de-oxidation H₂/N₂ reaction. Sequentially acid-washing, alkali-washing, water-washing processes. In the acid-washing process the concentration of HNO₃ is 0.5N, the concentration of NH₃.H₂O in the alkali-washing process is 5N, in water-washing process the deionized water is used to wash until getting to neutrality in electricity. Crushing, shifting with 350 meshes screen, examining goods and packaging are carried out in the finishing process.

### The Third Embodiment

Similar to the first embodiment of the present invention, the raw material is selected from Y₂O₃, Gd₂O₃, CeO₂, Tb₄O₇, Pr₆O₁₁, Dy₂O₃, Al₂O₃ and Ga₂O₃, the composition formula (Y₁₋ₓGdₓ)_{3-z}(Al_{1-y}Gay)₅O₁₂:Ce_{z}³⁺ wherein x is 0.3 mol/mol, y is 0.25 mol/mol, z is 0.06 mol/mol, Y, Gd, Al and Ga all are host cation and host anion, said sensitizer includes rare sensitizer Ce³⁺ and other aid-sensitizer Dy, the concentration of Dy is 7% of the Ce³⁺'s, the purity of the raw material is 5N, and the grain fineness is 1 um. Then taking out the raw materials for extracting former body by means of homogeneous-deposition process, the pH value of the homogeneous-deposition is controlled in 7, the precipitant is liquid ammonia adding with 1.0 mol/L Al(OH)₃ liquor, and mixing up, the temperature of the mixed solution is controlled in 80° C., so as to generate co-deposition, said deposition is treated in centrifuging, washing, filtering and baking processes to extract the sphericized or director-sphericized YAG former body. Next the former body is mixed with fluxing agents BaF₂ and NH₄F; said fluxing agents are 4% of the former body in content. Composing is took part in at 1300° C. for 1 hours in de-oxidation H₂/N₂ reaction. Sequentially acid-washing, alkali-washing, water-washing processes. In the acid-washing process the concentration of HNO₃ is 3N, the concentration of NH₃.H₂O in the alkali-washing process is 3N, in water-washing process distilled water is used to wash until getting to neutrality in electricity. Crushing, shifting with 350 meshes screen, examining goods and packaging are carried out in the finishing process.

### The Fourth Embodiment

Similar to the first embodiment of the present invention, the raw material is selected from Y₂O₃, Gd₂O₃, CeO₂, Tb₄O₇, Pr₆O₁₁, Dy₂O₃, Al₂O₃ and Ga₂O₃, the composition formula 2:Ce wherein x is 0.35 mol/mol, y is 0.35 mol/mol, z is 0.08 mol/mol, Y, Gd, Al and Ga all are host cation and host anion, said sensitizer includes rare sensitizer Ce³⁺ and other aid-sensitizers Pr and Tb, the concentrations of Pr and Tb are individually 5% and 6% of the Ce³⁺'s, the purity of the raw material is 4N, and the grain fineness is 1.5 um. Then taking out the raw materials for extracting former body by means of homogeneous-deposition process, the pH value of the homogeneous-deposition is controlled in 7.5, the precipitant is liquid ammonia adding with 1.2 mol/L Al(OH)₃ liquor, and mixing up, the temperature of the mixed solution is controlled in 85° C., so as to generate co-deposition, said deposition is treated in centrifuging, washing, filtering and baking processes to extract the sphericized or director-sphericized YAG former body. Next the former body is mixed with fluxing agents NH₄F and NH₄Cl; said fluxing agents are 3.5% of the former body in content. Composing is took part in at 1600° C. for 2.5 hours in de-oxidation H₂/N₂ reaction. Sequentially acid-washing, alkali-washing, water-washing processes. In the acid-washing process the concentration of HNO₃ is 4N, the concentration of NH₃.H₂O in the alkali-washing process is 0.5N, in water-washing process distilled water is used to wash until getting to neutrality in electricity. Crushing, shifting with 350 meshes screen, examining goods and packaging are carried out in the finishing process.

### The Fifth Embodiment

Similar to the first embodiment of the present invention, the raw material is selected from Y₂O₃, Gd₂O₃, CeO₂, Tb₄O₇, Pr₆O₁₁, Dy₂O₃, Al₂O₃ and Ga₂O₃, the composition formula (Y₁₋ₓGdₓ)_{3-z}(Al_{1-y}Gay)₅O₁₂:Ce_{z}³⁺, wherein x is 0.4 mol/mol, y is 0 mol/mol, z is 0.09 mol/mol, Y, Gd, Al and Ga all are host cation and host anion, said sensitizer includes rare sensitizer Ce³⁺ and other aid-sensitizers Pr, Tb and Dy, the concentrations of Pr, Tb and Dy are individually 7%, 5% and 6% of the Ce³⁺'s, the purity of the raw material is 4N, and the grain fineness is 2 um. Then taking out the raw materials for extracting former body by means of homogeneous-deposition process, the pH value of the homogeneous-deposition is controlled in 8, the precipitant is liquid ammonia adding with 0.8 mol/L Al(OH)₃ liquor, and mixing up, the temperature of the mixed solution is controlled in 90° C., so as to generate co-deposition, said deposition is treated in centrifuging, washing, filtering and baking processes to extract the sphericized or director-sphericized YAG former body. Next the former body is mixed with fluxing agents B₂O₃, AlF₃ and BaF₂; said fluxing agents are 4% of the former body in content. Composing is took part in at 1450° C. for 4 hours in de-oxidation H₂/N₂ reaction. Sequentially acid-washing, alkali-washing, water-washing processes. In the acid-washing process the concentration of HNO₃ is 1N, the concentration of NH₃.H₂O in the alkali-washing process is 4N, in water-washing process deionized water is used to wash until getting to neutrality in electricity. Crushing, shifting with 350 meshes screen, examining goods and packaging are carried out in the finishing process.

### The Sixth Embodiment

Similar to the first embodiment of the present invention, the raw material is selected from Y₂O₃, Gd₂O₃, CeO₂, Tb₄O₇, Pr₆O₁₁, Dy₂O₃, Al₂O₃ and Ga₂O₃, the composition formula (Y₁₋ₓGdₓ)_{3-z}(Al_{1-y}Gay)₅O₁₂:Ce_{z}³⁺, wherein x is 0.45 mol/mol, y is 0.2 mol/mol, z is 0.11 mol/mol, Y, Gd, Al and Ga all are host cation and host anion, said sensitizer includes rare sensitizer Ce³⁺ and other aid-sensitizers Pr and Dy, the concentrations of Pr and Dy are individually 6% and 5% of the Ce³⁺'s, the purity of the raw material is 5N, and the grain fineness is 1 um. Then taking out the raw materials for extracting former body by means of homogeneous-deposition process, the pH value of the homogeneous-deposition is controlled in 7, the precipitant is liquid ammonia adding with 0.7 mol/L Al(OH)₃ liquor, and mixing up, the temperature of the mixed solution is controlled in 80° C., so as to generate co-deposition, said deposition is treated in centrifuging, washing, filtering and baking processes to extract the sphericized or director-sphericized YAG former body. Next the former body is mixed with fluxing agent AlCl₃; said fluxing agent is 5% of the former body in content. Composing is took part in at 1500° C. for 3.5 hours in de-oxidation H₂/N₂ reaction. Putting water, corundum sphere and synthetic fried powder into a depolymerizing reactor takes part in de-polymerizing reaction for 1 hour, according to the mass ratio of water:corundum sphere:fried powder=4:1:1. By sifting with 350 meshes standard screen, it should be washed with 0.5N HNO₃ liquor at 80° C., and then centrifuged, next braked at 80° C. for 16 hours, after braking process, it should be crushed and screened with 250 meshes standard screen. Sequentially acid-washing, alkali-washing, water-washing processes. In the acid-washing process the concentration of HNO₃ is 2N, the concentration of NH₃.H₂O in the alkali-washing process is 4N, in water-washing process deionized water is used to wash until getting to neutrality in electricity. Crushing, shifting with 350 meshes screen, examining goods and packaging are carried out in the finishing process.

### The Seventh Embodiment

Similar to the sixth embodiment of the present invention, the difference is that after composing process is took part in de-oxidation H₂/N₂ reaction, putting water, corundum sphere and synthetic fried powder into a depolymerizing reactor takes part in depolymerizing reaction for 1 hour, according to the mass ratio of water:corundum sphere:fried powder=4:1:1. By sifting with 350 meshes standard screen, it should be washed with 5NHNO₃ liquor at 90° C., and then centrifuged, next braked at 80° C. for 16 hours, after braking process, it should be crushed and screened with 250 meshes standard screen.

### The Eighth Embodiment

Similar to the first embodiment of the present invention, the difference is that after taking out the row material, the former body can be extracted by sol-gel process. The pH value of rare nitrate liquid in the raw material is controlled in the range from 2 to 3 mixing with lemon acid in the ratio of 1:2 of the raw material:the lemon acid, then adding with Aluminum nitric liquid with 0.6˜1.2 mol/L concentration, then adding polyethylene glycol until getting to homogeneous, next mixing with intermixture to compose collosol, after the collosol to be transformed into gelatinous, braking the gelatinous at 110˜120° C. into dry, then the dry gelatinous is grinded into powder, next is sintered at 900° C. for 4˜6 hours to form the former body with 1˜2 um grain fineness.

I claim:

1. A phosphor of white LED, wherein, the general formula (Y₁₋ₓGdₓ)_{3-z}(Al_{1-y}Ga_{y}) 5012:Ce_{z}³⁺ therein 0≦x≦0.45 mol/mol, 0≦Y≦0.55 mol/mol, 0.06≦x≦0.12 mol/mol, the sensitizer includes rare sensitizer Ce³⁺ and other aid-sensitizers, where said aid-sensitizer is at least one of Pr, Tb, Dy and so on, the concentration of Pr, or Tb, or Dy is individually 5%˜10% of the Ce³⁺'s.

2. A manufacturing method of the phosphor claimed in claim 1 being following steps:
1) The raw material is selected from Y₂O₃, Gd₂O₃, Tb₄O₇, Pr₆O₁₁, Dy₂O₃, Al₂O₃ and Ga₂O₃, the composition formula (Y₁₋ₓGdₓ)_{3-z}(Al_{1-y}Gay)₅O₁₂:Ce_{z}³⁺, wherein 0≦X≦0.45 mol/mol, 0≦Y≦0.55 mol/mol, 0.06≦z≦0.12 mol/mol, Y, Gd, Al and Ga all are the host cation and the host anion, said sensitizer includes rare sensitizer Ce³⁺ and other aid-sensitizers, wherein said aid-sensitizer is at least one of Pr, Th, Dy and so on, the concentration of Pr, or Tb, or Dy is individually 5%˜10% of the Ce³⁺'s, the purity of the raw material is 4˜5N, and the grain fineness is 1˜2 um.
2) Then taking out the raw materials for extracting former body, the grain fineness of the sphericized or director-sphericized grain of the former body extracted is 1˜2 um.
3) In mixing fluxing agent into the former body, said fluxing agent is 1˜5% of the former body in content, and is at least one of B₂O₃, AlF₃, AlCl₃, BaF₂, NH₄F, NH₄Cl and so on.
4) composition process: composing is took part in at 1300°˜1600° C. for 1˜4 hours in de-oxidation H₂/N₂ reaction.
5) Finishing process: sequentially acid-washing, alkali-washing, water-washing processes. In the acid-washing process the concentration of HNO₃ is 0.5˜5N, the concentration of NH₃.H₂O in the alkali-washing process is 0.5˜5N, in water-washing process distilled water or deionized water is used to wash until getting to neutrality in electricity.
6) Crushing, shifting, examining goods and packaging.

3. A manufacturing method of the phosphor of white LED as claimed in claim 2, wherein said former body can be extracted by homogeneous-deposition process or sol-gel process.

4. A manufacturing method of the phosphor of white LED as claimed in claim 2, wherein the value of pH of the homogeneous deposition is controlled in the range from 6.5 to 8.0 by using homogeneous-deposition method, said precipitant is liquid ammonia mixing with Al(OH)₃ with 0.6˜1.2 mol/L concentration in the liquid temperature controlled in the range of 75˜90° C. until generating co-precipitation; by centrifuging, washing, filtering and baking processes the deposition is extracted into YAG former body.

5. A manufacturing method of the phosphor of white LED as claimed in claim 2, wherein by using said sol-gel process the pH value of rare nitrate liquid in the raw material is controlled in the range from 2 to 3 mixing with lemon acid in the ratio of 1:2 of the raw material and the lemon acid, then adding with Aluminum nitric liquid with 0.6˜1.2 mol/L concentration, then adding polyethylene glycol until getting to homogeneous, next mixing with intermixture to compose collosol, after the collosol to be transformed into gelatinous, braking the gelatinous at 110˜120° C. into dry, then the dry gelatinous is grinded into powder, next is sintered at 900° C. for 4˜6 hours to form the former body.

6. A manufacturing method of the phosphor of white LED as claimed in claim 2, wherein in said finishing process, putting water, corundum sphere and fried powder into a depolymerizing reactor takes part in de-polymerizing reaction for 1 hour; by sifting with 350 meshes standard screen, it should be washed with 0.5˜5NHNO₃ liquor at the range from 80° C. to 90° C., and then centrifuged, next braked at 80° C. for 16 hours, after braking process, it should be crushed and screened with 250 meshes standard screen.

7. A manufacturing method of the phosphor of white LED as claimed in claim 2, wherein the mass ratio of water:corundum sphere:fried powder=4:1:1.
